(19) United States
(12) Patent Application Publication
(10) Pub. No.: US 2009/0057885 A1
(43) Pub. Date: Mar. 5, 2009

(54) SEMICONDUCTOR DEVICE

(75) Inventor: Horst Theuss, Wenzenbach (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 11/847,748

(22) Filed: Aug. 30, 2007

(51) Int. Cl. H01L 23/28; H01L 21/00

(52) U.S. Cl. 257/723; 257/787; 438/127; 257/E23.116

(57) ABSTRACT

A semiconductor device is disclosed. One embodiment provides a semiconductor chip having a main surface, wherein a first molding compound accommodates the semiconductor chip. The first molding compound has a surface that is substantially coplanar to the main surface of the semiconductor chip. A second molding compound is arranged in a space between the first molding compound and the semiconductor chip.

### BACKGROUND

This invention relates to semiconductor devices and more particularly to the technique of embedding semiconductor chips in molding compounds.

Semiconductor devices include one or more semiconductor chips having internal semiconductor structures and possibly internal mechanical structures. Typically, the semiconductor chips of such devices are packaged in plastics. Due to interactions occurring between package and semiconductor chip the performance of such semiconductor devices may be affected.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 schematically illustrates a device of a first embodiment.

FIG. 2 schematically illustrates a device of a second embodiment.

FIG. 3 schematically illustrates a device of a first embodiment having a second molding compound covering only one main surface of the semiconductor chip.

FIG. 4 schematically illustrates a device of a third embodiment including an additional semiconductor chip mounted side by side to a first semiconductor chip.

FIGS. 5A to 5G schematically illustrate a method to manufacture a device.

FIGS. 6A to 6G schematically illustrate a method to manufacture a device including an additional semiconductor chip mounted side by side to a first semiconductor chip.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

Devices with semiconductor chips embedded in molding compounds are described below. The semiconductor chips may be of different types and may include for example integrated electrical or electro-optical circuits. The semiconductor chips may be configured to include movable mechanical members which are formed as micro-mechanical structures, such as bridges, membranes or tongue structures. Chips including such structures are also known under the term “micro-electro mechanical system” or briefly MEMS. The semiconductor chips may be configured as sensors or actuators, for example pressure sensors, acceleration sensors, rotation sensors, angular position sensors, motion sensors, microphones, Hall-sensors or GMR-sensors (GMR: Giant-Magneto-Resistance) etc. Semiconductor chips in which such functional elements are embedded generally contain electronic circuits which serve for driving the functional elements and/or for processing signals generated by the functional elements. The semiconductor chips need not be manufactured from specific semiconductor material and, furthermore, may contain inorganic and/or organic materials that are not semiconductors, such as for example metals, insulators or plastics.

The semiconductor chips may have contact pads which allow electrical contact to be made with the chips. The contact pads may be composed of any desired electrical conductive material, for example of a metal such as aluminum, gold or copper, a metal alloy or an electrically conductive organic material. The contact pads may be situated on the active surfaces of the semiconductor chips or on other surfaces of the semiconductor chips.

The devices described in the following include a first molding compound, a second molding compound and a semiconductor chip. The second molding compound covers at least parts of the semiconductor chip and is located in a space between the semiconductor chip and the first molding compound. At first the properties of the second molding compound will be described.

The second molding compound may be made of an elastomere, e.g., a curable liquid which, in the cured state, is more elastic than the first molding compound. More specifically, the second molding compound may consist of a silicone, e.g., a high temperature vulcanizing silicone (HTV-silicone) which, under crosslinking processes generated by thermal load, will become silicone rubber. Even in the cured state these silicone rubbers are plastically deformable and still capable of flowing. They belong to the class of elastomers. Suitable silicone rubbers are marketed for example from the company “Wacker Chemie AG” under the trade names “ELASTOSIL”, “SEMICOSIL” or “GENIOMER”.

Various techniques may be employed for the application of the second molding compound onto the semiconductor chip. Possible techniques are for example compression molding, in which the semiconductor chip and the liquid molding material are inserted in first mold and are subjected to pressure exerted by a second mold (punch), injection molding, in which the liquid molding material is injected in a closed cavity mold tool containing the semiconductor chip, casting, in which an open cavity mold is used to receive the liquid molding material, or dispensing, which may be carried out as a mold-free process and in which a predefined amount of liquid molding material is supplied to the semiconductor chip. The viscosity of the second molding compound (after curing) may be chosen in a wide range offered by commercial available HTV-silicones, and adding a filler to the HTV-silicone may be used to finely adapt their viscosity.

HTV-silicones are usually filled with different amounts of filling material consisting of small particles of glass with maximum diameters in the range of 5 to 100 μm. The viscosity of the second molding compound may be in the range of 100 to 10000 Pa·s, preferable below 3000 Pa·s, more preferably about or below 2000 Pa·s.

Since the second molding compound may belong to the group of elastomers, its elasticity is usually much higher than the elasticity of moldable plastics used for the first molding compound. Thus, the second molding compound may absorb stress or tensions well and does not, or only to a very limited extent, transfer stress or tensions from the first molding compound to the chip or at least to a specifically sensitive part of the chip. Furthermore, the viscosity of solid plastics typically used for packages for semiconductor chips, i.e. the viscosity of the first molding compound, is nearly infinite or at least one or many orders of magnitude higher than the viscosity of the second molding compound.

The first molding compound may be made of any appropriate thermoplastic or thermosetting material. Various techniques may be employed to cover the semiconductor chip and/or the second molding compound with the first molding compound, for example compression molding or injection molding. The covering of the semiconductor chip and/or the second molding compound by the first molding compound is done in a way that one surface of the first molding compound and one main surface of the semiconductor chip are substantially aligned in a coplanar relationship, i.e. extend in the same plane.

Between the first molding compound and the semiconductor chip may be a spacing which may be filled with the second molding compound. The second molding compound may also have a surface which is coplanarily aligned with the first molding compound and one main surface of the semiconductor chip. In this way, an extended connection area is formed by the coplanar surfaces which may be used for electrically connecting the chip-package to a carrier such as a customer's application board.

This connection area may be equipped with a first metallization to generate electrical conductive structures and external terminals. That is, the first metallization may be applied to the semiconductor chip and, where appropriate, also to the coplanar surfaces of the first and second molding compound. The first metallization may be used to electrically couple contact pads of the semiconductor chip (or chips, if more than one chip are accommodated in the first molding compound) to external contact terminals. The first metallization may be a redistribution layer or may be a part of it and may be manufactured with any desired geometric shape and any desired material composition. The first metallization may, for example, be composed of linear conductor tracks, or may have structures of specific shapes, for example to form inductor coils, but may also be designed to form a continuous layer covering a specific area. Any desired electrical conductive material such as metals, for example aluminum, gold or copper, metal alloys or organic conductors, may be used as the material.

The first metallization may be arranged above or below or between dielectric layers. The first main surface of the semiconductor chip and the first metallization may be separated by a dielectric polymer layer or by a Si₃N₄— or a SiO₂-layer. Furthermore, several metallizations my be stacked on top of each other, for example, in order to obtain conductor tracks crossing each other wherein the metallizations are separated by each other by a dielectric layer. The metallizations may be manufactured by using thin film techniques like photolithographic processes or by thick film techniques in which the conductor tracks are typically generated by printing or dispensing processes.

FIG. 1 schematically illustrates a device 100-1 of a first embodiment. A first molding compound 101 accommodates a first semiconductor chip 102 wherein the first semiconductor chip 102 has a first main surface 103 which is substantially coplanar to a surface 104 of the first molding compound 101. A second molding compound 105 is disposed between the first molding compound 101 and the semiconductor chip 102. The second molding compound 105 may be a HTV-silicone which surrounds all side walls 106 and the second main surface 107 of the first semiconductor chip 102 which is opposite to the first main surface 103. Since the first molding compound 101 is arranged to encompass the second molding compound 105, it also surrounds the side faces 106 of the first semiconductor chip 102 and the second main surface 107 of the semiconductor chip 102.

The more the thickness of the second molding compound 105 is increased, the better is the cushioning effect thereof. The second molding compound 105 may at least partially provide for a distance between a surface (side walls 106 or second main surface 107) of the first semiconductor chip 102 and the first molding compound 101 that is greater than one or more millimeters, e.g., more particularly greater than 3 millimeters. However, even a thickness smaller than 1 millimeter of the second molding compound 105 (for instance a thickness of more than 0.1 millimeter) may be effective in cushioning the first semiconductor chip 102. As is apparent from FIG. 1, the thickness of the second molding compound 105 (i.e. the distance between a surface of the first semiconductor chip 102 and the first molding compound 101) may vary and the values of thickness referred to above are not necessarily (none the less could be) observed at all surface locations of the first semiconductor chip 102.

The second molding compound 105 may have a curved top surface. Such curved top surface may result from the manufacturing process used for generating the second molding compound 105. In particular, if a mold-free dispensing process is used for generating the second molding compound 105, a curved top surface of the second molding compound 105 will be produced.

In conventional structures where no second molding compound 105 is present, the chip may be subjected to stress, which may be caused by a mismatch of the thermal expansion coefficients between the package and semiconductor chip or by mechanical causes such as the mounting of the package on an application board. These effects may deteriorate the performance or result in a malfunction of devices including, for example, sensitive elements like movable mechanical members or pressure sensitive components. These effects are efficiently reduced by introducing an elastic bed or cushion represented by the second molding compound 105 into the package.

The first molding compound 101, the second molding compound 105 and the first semiconductor chip 102 form a common plane which may be equipped with a first metallization 108 which is used to connect chip pads 118 to external contact elements 113 of the device 100-1. The first metallization 108 may be designed to form conductor paths and device pads 119. The external contact elements 113, which are attached to the device pads, may be configured e.g., as solder balls or the like. The first metallization 108 may further extend over the surface of the second molding compound 105 and also over the surface of the first molding compound 101. The device pads 119 and the contact elements 113 may be located at any convenient position across the first metallization 108, i.e. over the main surface 103 of the first semiconductor chip 102, over the surface of the second molding compound 105 and/or over the surface of the first molding compound 101. The first metallization 108 may be embedded in dielectric polymer layers or it may be deposited on a passivation layer of the first semiconductor chip 102 which can be generated directly on the surface of the first semiconductor chip 102 by an oxiding or nitration process.

Further, the device 100-1 may have an opening 109 in the first metallization 108 to provide access to an external influencing quantity like sound, pressure, light or the like to a sensing area 110 of the first semiconductor chip 102. This sensing area 110 may include a mechanical movable member such as a membrane or a tongue structure. It might also be a photosensitive area or an area which is sensitive to gases or moisture.

Further embodiments are illustrated in FIGS. 2 to 4. These embodiments are similar to the embodiment of FIG. 1. Therefore, the features described above in conjunction with FIG. 1 are also related to these embodiments except for the modifications described further below.

In the device 100-1 illustrated in FIG. 1 the first main surface 103 of the first semiconductor chip 102 is the active surface which includes active elements, contact pads and mechanical members, if any. It is also possible to embed the first semiconductor chip 102 in reversed (or flipped) orientation which results in that the first main surface 103 of the semiconductor chip 102 is the surface opposite to the active surface as illustrated in the device 100-2 of FIG. 2. In this case the surface of the first semiconductor chip 102 opposite to the active surface is equipped with the first metallization 108. In this reversed orientation the semiconductor chip 102 may be provided with electrical conductive feedthroughs 111 extending from one main surface of the first semiconductor chip 102 to the other main surface of the first semiconductor chip 102 to electrically couple the contact pads 112 on the active surface of the semiconductor chip 102 to the contact elements 113 connected to the first metallization 108. The feedthroughs 111 may be generated by laser ablation, mechanical drilling or printing techniques in the semiconductor chip. They may have an inner diameter in the range of e.g., 100 to 500 μm and they may be plated with a metallization layer and/or filled with a conductive material.

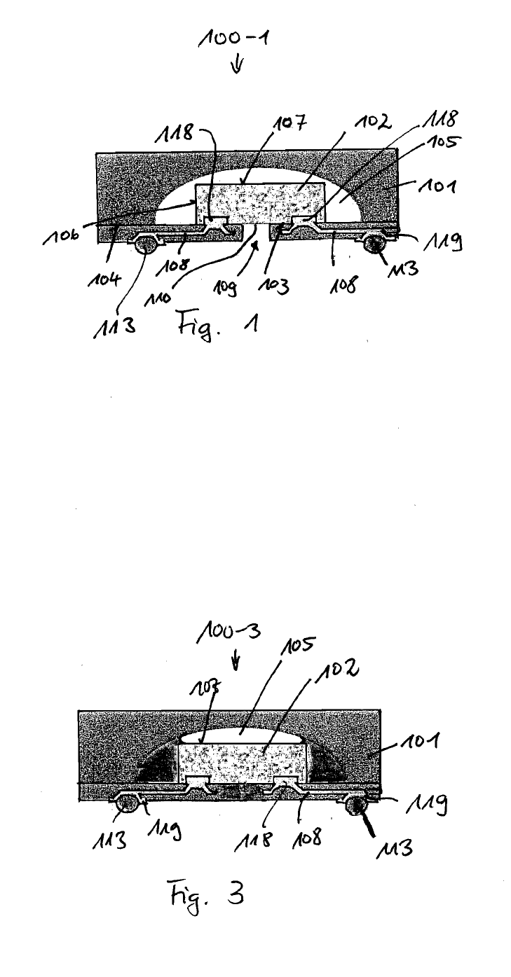

Some kinds of chips are either relative insensitive or only locally sensitive against stress and thus only a small amount of the second molding compound 105 may be sufficient. In this case a device 100-3 may be designed in which substantially only the second main surface 107 of the first semiconductor chip 102 (FIG. 3) is covered with the second molding compound 105, whereas the side faces of the semiconductor chip 102 are in direct contact with the first molding compound 101. If the first semiconductor chip 102 needs no access to the environment the first metallization 108 may be designed without opening 109.

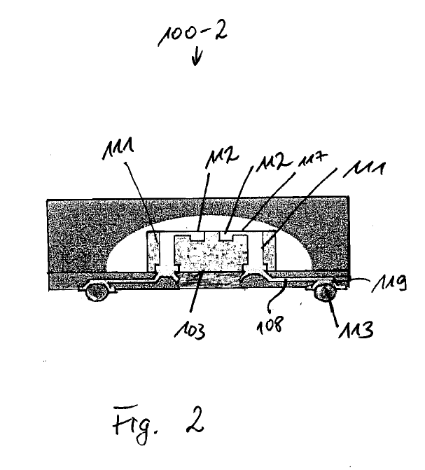

The device 100-4 of FIG. 4 further includes a second semiconductor chip 120 which may be arranged side by side to the first semiconductor chip 102 and may have a surface which is substantially coplanarily aligned to the first main surface 103 of the first semiconductor chip 102. The second semiconductor chip 120 may be embedded in the first molding compound 101 and may be electrically interconnected to the first semiconductor chip 102 via conductor paths 114 which may form part of the first metallization 108. The second semiconductor chip 120 may implement a driver circuitry for driving the first semiconductor chip 102 and/or a signal processing circuitry for processing one or more output signals generated by the first semiconductor chip 102.

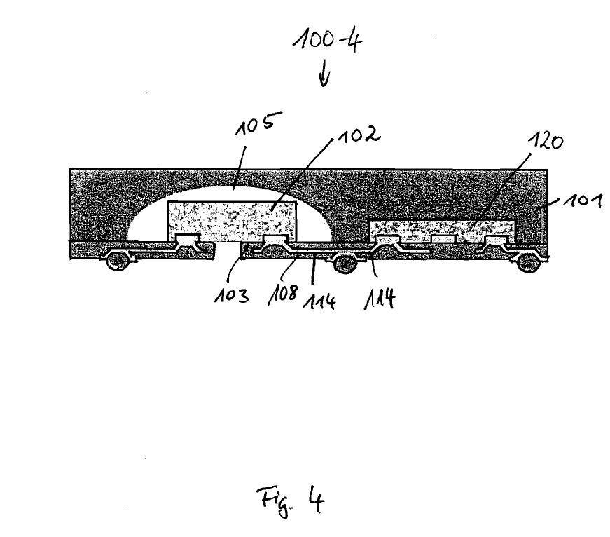

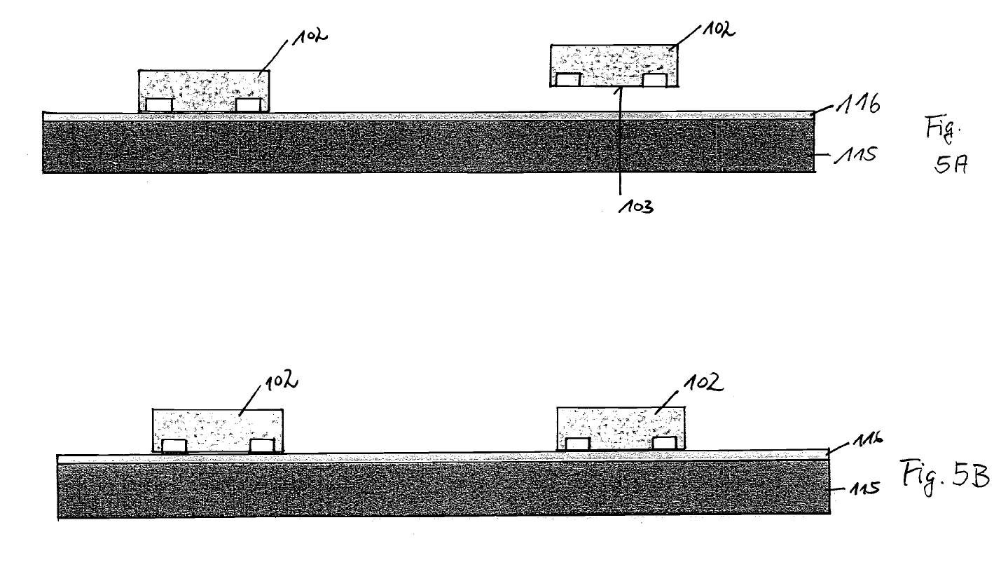

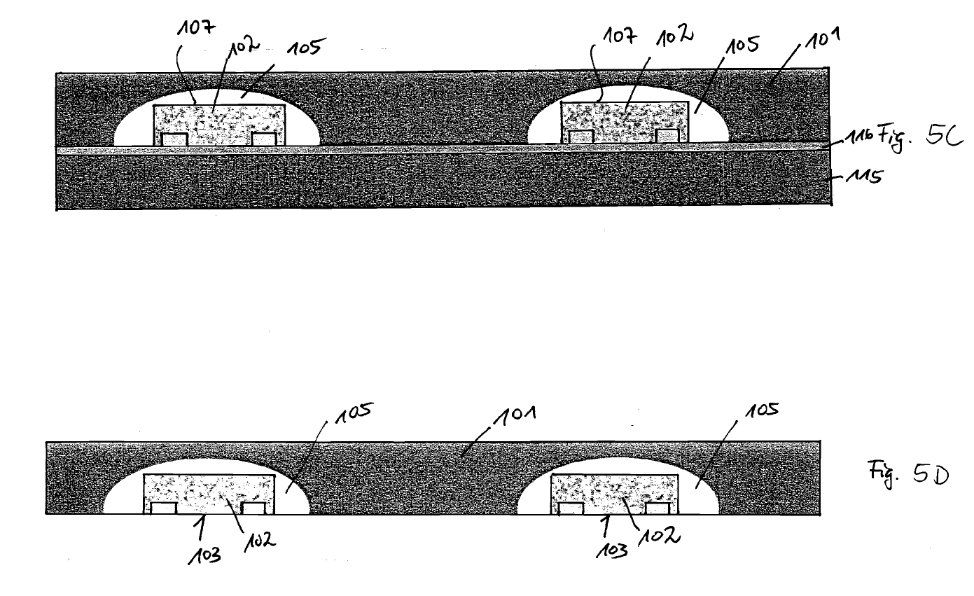

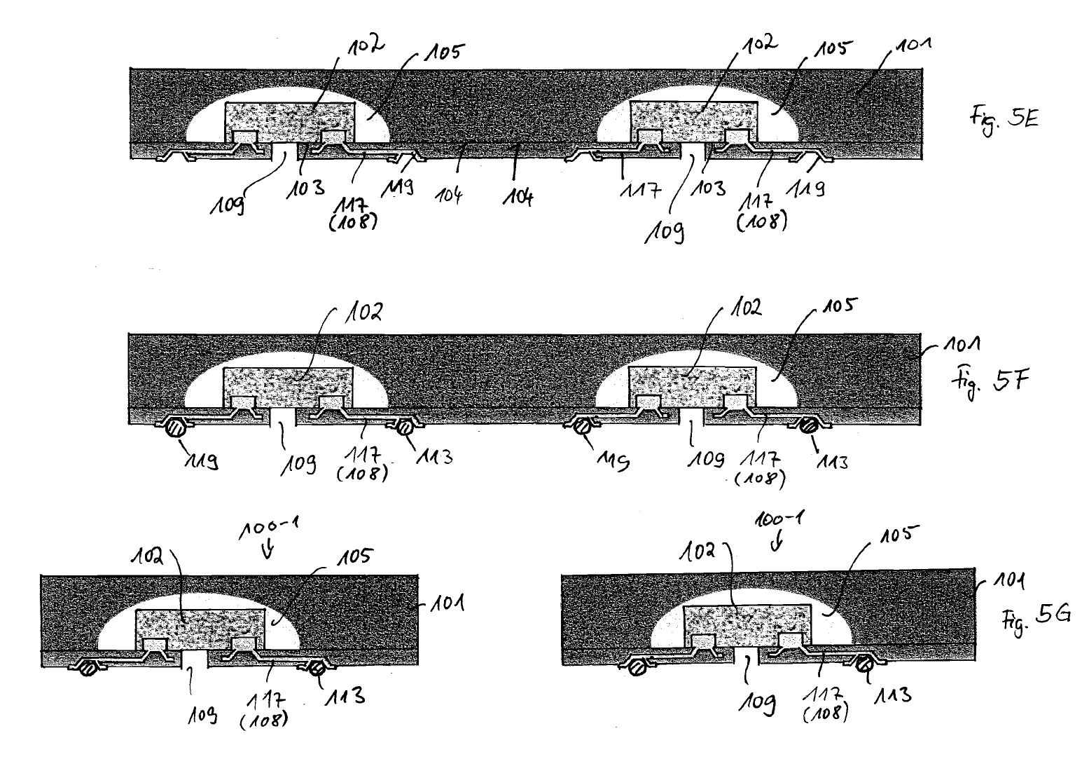

FIGS. 5A to 5G schematically illustrate a method to manufacture a device 100-1, a cross section of which is illustrated in FIG. 5G. First, semiconductor chips 102 which are used to fabricate the device 100-1 are produced from a wafer made of semiconductor material such as e.g., silicon (not illustrated). After dicing the wafer (not illustrated) into the first semiconductor chips 102, the first semiconductor chips 102 are relocated with their first main surfaces 103 (FIG. 5A) on a carrier 115 in a spaced-apart relationship (FIG. 5B). To attach the first semiconductor chips 102 on the carrier 115 a double sided adhesive tape 116 may, for example, be laminated onto the carrier 115 prior to the attachment of the first semiconductor chips 102. Other kinds of adhesive materials may alternatively be used.

After mounting the first semiconductor chips 102 on the carrier 115 they are covered with the second molding compound 105. For the second molding compound 105 an elastomer such as a HTV-silicone may be used. To cover the first semiconductor chips 102 a dispensing process may be utilized. To this end, a predefined amount of the second molding compound 105 as a liquid is deposited on the second main surface 107 of each first semiconductor chip 102. The predefined amount spreads out to cover the first semiconductor chips 102. The extent of covering is dependent on the chosen amount of the second molding compound 105 and on physical properties such as viscosity, surface tension etc. It may be chosen an amount that covers the second main surfaces 107 and all side walls 106 of the first semiconductor chips 102 or an amount that covers only the second main surfaces 107 of the first semiconductor chips 102. Further, the physical properties of the liquid second molding compound 105 may be chosen to guarantee for a sufficient thickness of the second molding compound 105 after curing.

Alternatively, an injection molding, compression molding or casting process may be utilized. To this end, molds are deposed on the carrier 115 each surrounding a first semiconductor chip 102. The molds may either form closed or open cavity structures on the carrier 115. These molds are then filled with the material of which the second molding compound 105 is to be made. Then, a curing process follows to harden the second molding compound 105. The curing process may be carried out at temperatures above 80° C. and in particular above 100° C. In the case of injection molding, compression molding or casting, the molds are removed after curing of the second molding compound 105.

After covering the first semiconductor chips 102 with the second molding compound 105 a first molding compound 101 is applied onto the second molding compound 105 (FIG. 5C). Again an injection molding, compression molding or casting process may be applied by utilizing a suitable mold. Typically, the first molding compound 101 completely encapsulates the first semiconductor chip 102 and the second molding compound 105 with the exception of the bottom surfaces thereof which are protected by the carrier 115. The first molding compound 101 may be made of a thermoplastic or thermosetting material which, compared to the second molding compound 105, is far less elastic or even essentially non-elastic after curing. The first molding compound 101 may be made of a composite material on the basis of epoxy resin, possibly containing further components such as phenolic hardeners, silicas etc.

The semiconductor chips 102 covered with the first and second molding compounds 101 and 105 are then released from the carrier 115 and the double sided adhesive tape 116 is peeled from the semiconductor chips 102 as well as from the first and second molding compounds 101 and 105 (FIG. 5D). That way, a configuration is created which is usually referred to as a “reconfigured wafer”. In the reconfigured wafer, all first main surfaces 103 of the first semiconductor chips 102 are coplanarily aligned and are uncovered of molding compounds.

Then the first metallization 108 is to be generated on the first main surface 103 of the first semiconductor chips 102 and on the coplanar surfaces of the first and second molding compounds 101 and 105 (FIG. 5E). To this end, thin-film or thick-film techniques may be used. In thin-film techniques, insulation and metal layers are typically deposited by processes which are commonly used in the semiconductor technology art, e.g., chemical vapor deposition (CVD), physical vapor deposition (PVD) or spin coating. Such layers are patterned or structured typically by lithographic processes. The thicknesses of such layers may be significantly less than 10 μm. Thick-film technologies, on the other hand, typically use conventional depositing processes such as lamination in order to apply insulating polymer layers and printing or dispensing processes in order to apply conductive structures. The thicknesses of such layers or structures are typically more than 10 μm.

By way of example, if a thin-film process is used, first an insulating layer is generated which may be a dielectric polymer layer or a (hard) passivation layer. A dielectric polymer layer may be a layer made of a photoresist or of any other etching resist, and may be deposited e.g., by CVD, PVD or spin coating. A passivation layer is made directly on the first main surfaces 103 of the first semiconductor chips 102 by generating e.g., a Si₃N₄— or a SiO₂-layer thereon. It is to be noted that such passivation layer may also be generated on the first main surfaces 103 before dicing the wafer. The dielectric polymer layer or the passivation layer may be structured to have openings 109 which provide access to the active surfaces of the first semiconductor chips 102.

Then the surface areas of the reconfigured wafer which are passivated or equipped with a polymer dielectric layer may be completely metallized with a metal layer. A standard metallization process may be used which may involve an evaporation of the desired metal or an electroless deposition process. In case of an electroless deposition process a seed layer, such as a palladium layer, may first be deposited on the insulating layer. Then a copper layer is electrolessly deposited. This copper layer may have a thickness of less than 1 μm. Thereafter, another layer of copper is galvanically deposited which may have a thickness of more than 5 μm.

The metal layer may then be structured in order to generate the first metallization 108 with the desired metallic structures using lithographic and etching processes. As a result, conductor tracks 117 of the first metallization 108 and device pads 119 are generated, establishing a “metallized reconfigured wafer”. Additionally, a second insulating layer, e.g., a polymer layer, may be generated on the first metallization 108. Subsequent metallizations and dielectric layers may follow.

As already mentioned, the first metallization 108 may have an opening 109 which will be provided by lithographic and etching processes of the passivation layer (if any), the dielectric polymer layers (if any) and the first metallization 108 or further metallizations (if any).

Then, solder balls 113 may be deposited on device pads 119 of the metallization 108 of the reconfigured wafer (FIG. 5F). In a subsequent process the chips are separated from each other for example by a sawing process, thus generating single devices 100-1 (FIG. 5G).

In some applications it could be advantageous to generate reconfigured wafers having first semiconductor chips 102 which are embedded in reversed orientation, like devices 100-2 which are illustrated in FIG. 2. Such first semiconductor chips 102 have an active surface which faces away from the first metallization 108. Before placing the first semiconductor chips 102 with their first main surfaces 103 on a carrier 115 such chips 102 may be prepared in the following way: conducting structures such as conductor tracks 117 and feedthroughs 111 are generated to route the signals of the first semiconductor chips 102 from the active surfaces to the first main surfaces 103 of the first semiconductor chips 102. The conductor tracks 117 may be part of the internal wiring of the first semiconductor chips 102 or they may be generated on insulating layers which are deposited onto the first semiconductor chips 102. The conductor tracks 117 are in electrical contact with the contact pads 112 of the semiconductor chips 102 and the feedthroughs 111 are in electrical contact with the conductor tracks 117 and extend from one main surface of the first semiconductor chips 102 to the other main surface of the semiconductor chips 102. They may be designed as essentially cylindrical holes with an inner conductive lining. Alternatively, the feedthroughs 111 can be filled with a conductive material such as e.g., solder. The feedthroughs 111 may be generated by drilling and/or laser ablation techniques and printing processes.

First semiconductor chips 102 prepared in that way may be mounted on the carrier 115 in reversed orientation and all subsequent processes to overmold them, to electrically couple them to a first metallization 108 and to separate each chip 102 from the others can be carried out in the same manner as described above in conjunction with FIGS. 5A to 5G. However, note that the first metallization 108 is not directly connected to elements of the active surface of the first semiconductor chips 102 but to the feedthroughs 111 of the first semiconductor chips 102. To this end, the dielectric layer which is deposited on the first main surface of the semiconductor chips 102 has openings at the positions of the feedthroughs 111.

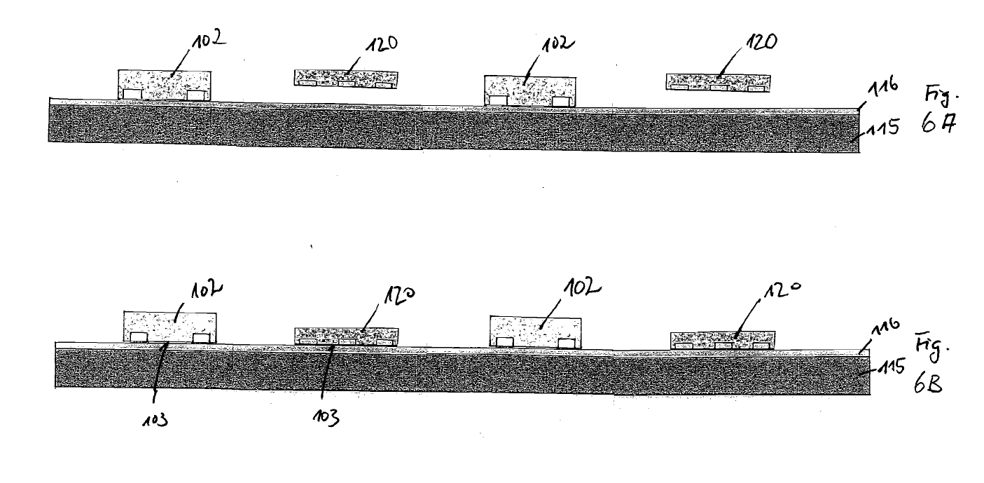

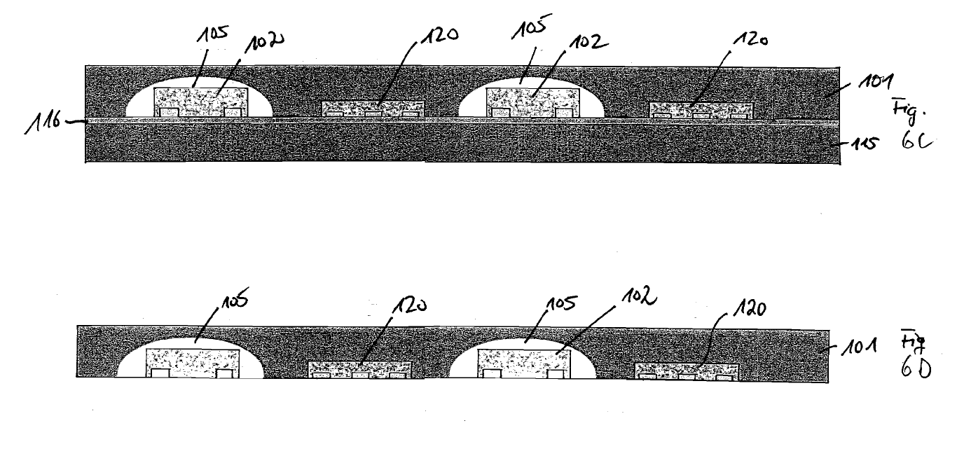

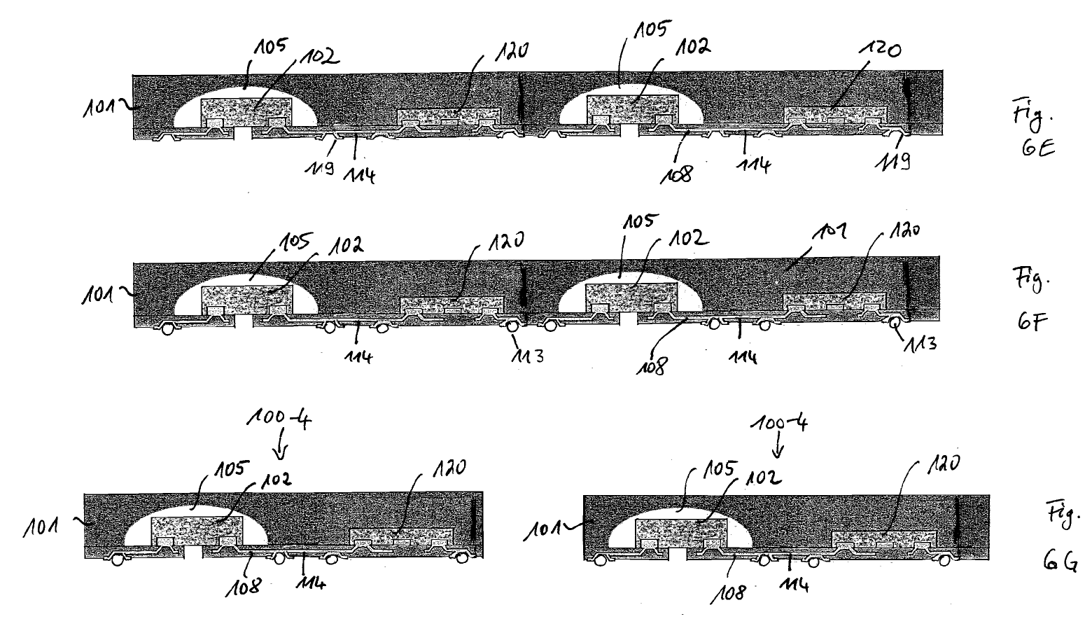

FIGS. 6A to 6G schematically illustrate a method to manufacture a device 100-4, a cross section of which is illustrated in FIG. 6G. First semiconductor chips 102 are produced on a first wafer made of semiconductor material (not illustrated). After dicing the first wafer (not illustrated) and separating the first semiconductor chips 102 (not illustrated), the first semiconductor chips 102 are relocated with their first main surfaces 103 (FIG. 6A) on a carrier 115 in a spaced-apart relationship (FIG. 6B). To attach the first semiconductor chips 102 on the carrier 115, a double sided adhesive tape 116 may, for example, be laminated onto the carrier 115 prior to the attachment of the first semiconductor chips 102. Again, other kinds of adhesive materials may alternatively be used. Further, second semiconductor chips 120 are produced from a second wafer made of semiconductor material (not illustrated). Alternatively, both the first and the second semiconductor chips 102 and 120 may be produced from the same wafer. After dicing the second wafer (not illustrated) to obtain the second semiconductor chips 120, the second semiconductor chips 120 are relocated with their first main surfaces 103 (FIG. 6A) on the carrier 115 between the first semiconductor chips 102 so that between each two chips 102, 120 still a spacing remains (FIG. 6B).

Then the first semiconductor chips 102 are covered with the second molding compound 105. The first semiconductor chips 102 may be covered in the same manner as described above in conjunction with FIGS. 1 to 5G. Then, a curing process follows which may be carried out the same way as described above.

After covering the first semiconductor chips 102 with the second molding compound 105, a first molding compound 101 is applied onto the second molding compound 105 and onto the second semiconductor chips 120 (FIG. 6C). Again, an injection molding, compression molding or casting process may be applied by utilizing a suitable mold. The processes “releasing the chips from the carrier 115”, “peeling the double sided adhesive tape 116 off the semiconductor chips 102 and 120 and off the first and second molding compounds 102 and 105”, “generating the first metallization 108”, “structuring and connecting the first metallization 108”, “depositing solder bumps 113 on the device pads 119” and “separating the reconfigured wafer into single devices (i.e. packages)” are described in conjunction with FIGS. 5D to 5G and are illustrated in FIGS. 6D to 6G. As a modification, the processes of generating and structuring the first metallization 108 now also involve the metallization area below the second semiconductor chip 120. The second semiconductor chip 120 is electrically connected by conductor paths 114 of the first metallization 108 which couple the second semiconductor chip 120 to the first semiconductor chip 102 or to device pads 119. Additionally, a second or further metallizations may be generated on the first metallization 108 to allow for crossings of conductor paths.

In a further embodiment the first semiconductor chips 102 may be mounted on the carrier 115 in reversed orientation to produce devices 100-4. By producing such devices, semiconductor chips 102 are used that are equipped with conductor tracks 117 and feedthroughs 111 to couple signals from the active surface to the first main surface 103. These first semiconductor chips 102 may be mounted on the carrier 115 as described in conjunction with FIGS. 6A to 6G but in reversed orientation. The processing illustrated in FIGS. 6A to 6G may be modified only with regard to the first metallization 108 which connects to the feedthroughs 111 of the first semiconductor chips 102 rather than to chip pads 118.

While a particular feature or aspect of an embodiment may have been disclosed specifically with respect to only one of several implementations, such feature or aspect may be combined with one or more other features or aspects of the other embodiments or implementations as may be desired and advantageous for any given or particular application.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device comprising:
a first semiconductor chip having a first main surface;
a first molding compound accommodating the first semiconductor chip and having a surface which is substantially coplanar to the first main surface of the chip; and
a second molding compound disposed between the first molding compound and the chip.

2. The device of claim 1, comprising wherein the elasticity of the second molding compound is higher than the elasticity of the first molding compound.

3. The device of claim 1, comprising wherein the first molding compound surrounds side faces of the first semiconductor chip and a second main surface of the semiconductor chip opposite to the first main surface.

4. The device of claim 1, wherein the second molding compound surrounds side faces of the first semiconductor chip and a second main surface of the semiconductor chip opposite to the first main surface.

5. The device of claim 1, comprising wherein the second molding compound covers substantially only a second main surface of the first semiconductor chip opposite to the first main surface.

6. The device of claim 1, comprising wherein the second molding compound having a surface which is substantially coplanar to the first main surface of the semiconductor chip.

7. The device of claim 6, comprising wherein the metallization extends over the surface of the second molding compound.

8. The device of claim 1, comprising wherein the first main surface is the active surface of the first semiconductor chip.

9. The device of claim 1, comprising wherein the first main surface is the surface opposite to the active surface of the semiconductor chip.

10. The device of claim 1, wherein a metallization is applied to the first main surface of the semiconductor chip.

11. The device of claim 10, comprising wherein an area adjacent to the first semiconductor chip remains free of the metallization.

12. The device of claim 1, comprising wherein the metallization extends over the surface of the first molding compound.

13. The device of claim 1, comprising wherein the second molding compound has a viscosity below 3000 Pa·s.

14. The device of claim 1, comprising a movable mechanical member.

15. A device comprising:
a first semiconductor chip;
a first molding compound at least partially surrounding the first semiconductor chip; and
a second molding compound between the first molding compound and the first semiconductor chip, the second molding compound having an elasticity different than the first molding compound.

16. The device of claim 15, comprising wherein at least a second semiconductor chip is embedded in the first molding compound.

17. The device of claim 16, comprising wherein the second semiconductor chip is electrically coupled to the first semiconductor chip.

18. The device of claim 16, comprising wherein the second semiconductor chip has a surface which is substantially coplanar to the first main surface of the first semiconductor chip.

19. A method comprising:
covering a first semiconductor chip with a second molding compound wherein a first surface of the first semiconductor chip remains uncovered; and
applying a first molding compound onto the second molding compound.

20. The method of claim 19, comprising placing the first semiconductor chip with its first main surface on a carrier before covering the first semiconductor chip with the second molding compound.

21. The method of claim 19, comprising using a second molding compound having an elasticity that is higher than the elasticity of the first molding compound.

22. The method of claim 19, further comprising:
curing the first molding compound after applying it onto the second molding compound.

23. The method of claim 19, further comprising:
applying a metallization to the first main surface of the first semiconductor chip.

24. The method of claim 23, further comprising:
coupling an active surface of the semiconductor chip electrically to the metallization.

25. The method of claim 19, further comprising:
coupling an active surface of the semiconductor chip electrically to at least one feedthrough.
